(19) United States
(12) Patent Application Publication
(10) Pub. No.: US 2025/0006461 A1
(43) Pub. Date: Jan. 2, 2025

(54) Plasma Processing Apparatus

(71) Applicant: Tokyo Electron Limited, Tokyo (JP)

(72) Inventor: Taro HAYAKAWA, Yamanashi (JP)

(21) Appl. No.: 18/745,926

(22) Filed: Jun. 17, 2024

(30) Foreign Application Priority Data
Jun. 29, 2023 (JP) 2023-106735
Mar. 19, 2024 (JP) 2024-044196

(51) Int. Cl. H01J 37/32

(52) U.S. Cl. CPC H01J 37/3211; H01J 37/3244

(57) ABSTRACT

A plasma processing apparatus is presented. The apparatus comprises: a processing chamber having an upper opening; a dielectric ceiling plate that partitions an inner space and an outer space of the processing chamber to close the opening, and has a plurality of recesses formed on a surface facing the outer space; and a plurality of electromagnetic wave supply parts respectively having flat antennas, respectively installed in the plurality of recesses, and configured to supply electromagnetic waves into the processing chamber. The antennas are disposed at bottom portions of the plurality of recesses.

### CROSS-REFERENCE TO RELATED APPLICATIONS

This application claims priority to Japanese Patent Applications No. 2023-106735 filed on Jun. 29, 2023 and No. 2024-044196 filed on Mar. 19, 2024, respectively, the entire contents of which are incorporated herein by reference.

### TECHNICAL FIELD

The present disclosure relates to a plasma processing apparatus.

### BACKGROUND

For example, Japanese Patent Application Publication No. 2012-216745 proposes a microwave introducing device that generates plasma from a processing gas using microwaves introduced into a processing chamber and performs plasma processing on a substrate. A conductive member constituting a ceiling wall is disposed at the ceiling of the processing chamber. The conductive member has a plurality of openings, a plurality of dielectric windows are fitted into the plurality of openings, thereby introducing microwaves into the processing chamber through the dielectric windows.

### SUMMARY

The present disclosure provides a technique capable of facilitating adjustment of plasma distribution in a plasma processing apparatus having a plurality of electromagnetic wave supply parts.

One aspect of the present disclosures relates to a plasma processing apparatus comprising: a processing chamber having an upper opening; a dielectric ceiling plate that partitions an inner space and an outer space of the processing chamber to close the opening, and has a plurality of recesses formed on a surface facing the outer space; and a plurality of electromagnetic wave supply parts respectively having flat antennas, respectively installed in the plurality of recesses, and configured to supply electromagnetic waves into the processing chamber, wherein the antennas are disposed at bottom portions of the plurality of recesses.

### BRIEF DESCRIPTION OF THE DRAWINGS

FIG. 1 is a schematic cross-sectional view showing an example of a plasma processing apparatus according to an embodiment.

FIGS. 2A and 2B are a cross-sectional view and a plan view of a dielectric ceiling plate according to a first embodiment, respectively.

FIG. 3 shows result example 1 of electric field intensity distribution and the dielectric ceiling plate according to the first embodiment.

FIGS. 4A and 4B are a cross-sectional view and a plan view of a dielectric ceiling plate according to a second embodiment, respectively.

FIG. 5 shows result example 2 of electric field intensity distribution and the dielectric ceiling plate according to the second embodiment.

FIG. 6 shows result example 3 of electric field intensity distribution and the dielectric ceiling plate according to the second embodiment.

FIGS. 7A and 7B are cross-sectional views and a plan view of a dielectric ceiling plate according to a third embodiment, respectively.

FIG. 8 shows cross-sectional views of a dielectric ceiling plate according to a reference example, a first embodiment, and a third embodiment.

FIG. 9 shows results examples of the electric field intensity distribution in the dielectric ceiling plates according to the reference example, the first embodiment, and the third embodiment.

FIG. 10 shows graphs showing result examples of the electric field intensity in a radial direction in the dielectric ceiling plates according to the reference example, the first embodiment, and the third embodiment.

### DETAILED DESCRIPTION

Hereinafter, embodiments for implementing the present disclosure will be described with reference to the accompanying drawings. Like reference numerals will be given to like parts throughout the drawings, and redundant description thereof may be omitted.

### (Plasma Processing Apparatus)

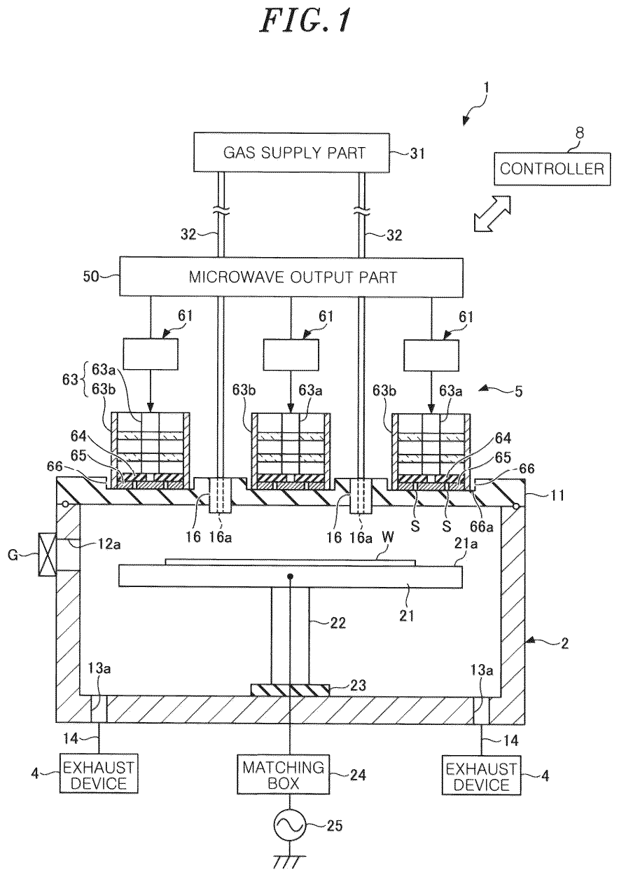

A configuration example of a plasma processing apparatus according to an embodiment will be described with reference to FIG. 1. FIG. 1 is a schematic cross-sectional view showing an example of a plasma processing apparatus 1 according to an embodiment. The plasma processing apparatus 1 includes a processing chamber 2 accommodating a substrate W, e.g., a semiconductor wafer, and a dielectric ceiling plate 11. The processing chamber 2 has an upper opening, and is formed in a substantially cylindrical shape. The processing chamber 2 is made of a metal material, e.g., aluminum or an alloy thereof. The dielectric ceiling plate 11 is disposed to close the opening of the processing chamber 2, and partitions an inner space and an outer space of the processing chamber 2. The inner space of the processing chamber 2 partitioned by the dielectric ceiling plate 11 is a vacuum side, and the outer space thereof is an atmospheric side. The dielectric ceiling plate 11 is made of a dielectric such as alumina (Al₂O₃) or the like. However, the dielectric ceiling plate 11 is not necessarily made of alumina. Further, the surface of the dielectric ceiling plate 11 that is in contact with the outer space is covered with a metal (not shown).

Further, the plasma processing apparatus 1 includes a gas supply part 31 that supplies a processing gas into the processing chamber 2, an exhaust device 4 that exhausts the processing chamber 2, and an electromagnetic wave supply part 5 that introduces electromagnetic waves into the processing chamber 2. In the present embodiment, microwaves with a frequency of 860 MHz are applied as an example of the electromagnetic waves. However, the electromagnetic waves are not limited to microwaves with a frequency of 860 MHz, and may be electromagnetic waves with a frequency of 300 MHz to 300 GHz.

A plurality of electromagnetic wave supply parts 5 are disposed on the surface (upper surface) of the dielectric ceiling plate 11 that faces the outer space of the processing chamber 2. Each of the electromagnetic wave supply parts 5 includes a coaxial waveguide 63 having an inner conductor 63a and an outer conductor 63b disposed outside the inner conductor 63a. The tip end of the inner conductor 63a is connected to an antenna 65 via a dielectric plate 64 having a conductor at the center thereof. In other words, the antenna 65 is disposed at an end portion of each of the plurality of electromagnetic wave supply parts 5.

The antenna 65 is made of a metal, and has a flat plate shape. A ring-shaped slot S is formed in the antenna 65. The antenna 65 has a radiation surface that radiates microwaves from the slot S. The dielectric plate 64 has a function of adjusting an impedance.

A plurality of recesses 66 are formed on the surface (upper surface) of the dielectric ceiling plate 11 that faces the outer space. The plurality of electromagnetic wave supply parts 5 are installed in the plurality of recesses 66 of the dielectric ceiling plate 11, respectively. The antenna 65 is disposed at a bottom portion 66a of each of the plurality of recesses 66.

The recess 66 has a planar shape that is circular or similar to that of the antenna 65. For example, when the antenna 65 has a circular shape (perfect circular shape), the planar shape of the recess 66 may be similar to that of the antenna 65. For example, when the antenna 65 has an elliptical shape, the recess 66 may have a circular planar shape.

A microwave output part has a distributor (not shown) and distributes microwaves using the distributor. The distributed microwaves are introduced into the electromagnetic wave supply parts 5 via microwave introducing modules 61, and propagate between the inner conductor 63a and the outer conductor 63b. The radiation surfaces of the antennas 65 that radiate microwaves are in contact with the bottom portions 66a of the recesses 66. With this configuration, the electromagnetic wave supply parts 5 radiate microwaves through the slots S of the antennas 65, and the microwaves propagate through the dielectric ceiling plate 11 and are supplied into the processing chamber 2. Due to the energy of the microwaves, a gas is decomposed near the surface (bottom surface) of the dielectric ceiling plate 11 that faces the inner space, and plasma is generated.

A placing table 21 is disposed in the processing chamber 2. The placing table 21 has a placing surface 21a, and the substrate W is placed on the placing surface 21a. The placing table 21 is supported by a support member 22, and insulated by an insulating member 23 disposed between the support member 22 and the processing chamber 2.

A plurality of (two in FIG. 1) exhaust ports 13a are formed at the bottom portion of the processing chamber 2. The exhaust device 4 is connected to the exhaust port 13a via an exhaust line 14. The exhaust device 4 reduces a pressure in the processing chamber 2 to a desired pressure (vacuum). A transfer port 12a for transferring a substrate W or the like is formed in the sidewall of the processing chamber 2. In the case of transferring the substrate W or the like, the transfer port 12a is opened and closed by a gate valve G.

A radio frequency (RF) bias power supply 25 is connected to the placing table 21 via a matching box 24. The RF bias power supply 25 supplies an RF power to the placing table 21 in order to attract ions to the substrate W.

The dielectric ceiling plate 11 has a plurality of gas holes 16a penetrating in a thickness direction through regions other than the recesses 66 that face the outer space and configured to supply a processing gas into the processing chamber 2. The plurality of gas holes 16a are formed in gas nozzles 16. The gas nozzles 16 are connected to a plurality of gas lines 32. The gas nozzles 16 are provided such that the tip ends of the gas nozzles 16 are located below the bottom surface of the dielectric ceiling plate 11. However, the tip ends of the gas nozzles 16 may be located at the same height as the bottom surface of the dielectric ceiling plate 11. The processing gas is supplied from the gas supply part 31, passes through the gas line 32 and the plurality of gas nozzles 16, and is supplied into the processing chamber 2 from the plurality of gas holes 16a. In one example, the plurality of gas holes 16a are evenly arranged in a circumferential direction between the electromagnetic wave supply part 5 located at the central portion and the plurality of electromagnetic wave supply parts 5 located at the outer peripheral portion.

A controller 8 processes computer-executable instructions that cause the plasma processing apparatus 1 to perform operations described in the present disclosure. In one embodiment, the controller 8 may be partially or entirely included in the plasma processing apparatus 1. In one embodiment, the controller 8 may be separate from the plasma processing apparatus 1, and may be connected to the plasma processing apparatus 1 to be communicable therewith. The controller 8 may include a processing part, a storage part, and a communication interface. The controller 8 is realized by, e.g., a computer. The processing part may be configured to read a program from the storage part and perform various control operations by executing the read program. The program may be stored in the storage part in advance, or may be acquired via a medium when necessary. The acquired program is stored in the storage part, and is read from the storage part and executed by the processing part. The medium may be various computer readable storage media, or may be a communications line connected to a communications interface. The processing part may be a central processing unit (CPU). The storage part may include a random access memory (RAM), a read only memory (ROM), a hard disk drive (HDD), a solid state drive (SSD), or a combination thereof. The communication interface may communicate with the plasma processing apparatus 1 via a communication line such as a local area network (LAN) or the like.

### (Dielectric Ceiling Plate)

A conductive member may be disposed, instead of the dielectric ceiling plate 11, at a ceiling plate of a conventional plasma processing apparatus. In this case, the conductive member has a plurality of openings, and dielectric windows are fitted into the openings, thereby introducing microwaves into the processing chamber through the dielectric windows.

In this configuration, plasma is locally generated below the dielectric windows. Therefore, the plasma distribution can be adjusted by individually adjusting the local plasma intensities. Further, in order to uniformly supply plasma onto the substrate, a distance (gap) from the dielectric windows to the placing table 21 is increased to allow the plasma to be diffused in the space. Accordingly, the distance (gap) needs to increases to a certain extent, which hinders scaling down of the device. Further, in this configuration, a gap may be generated between the conductive member and the dielectric windows, and particles may be generated. Particularly, particles are likely to be generated under low-pressure process conditions.

On the other hand, in the plasma processing apparatus 1 according to the present embodiment, a single dielectric ceiling plate 11 constitutes the ceiling wall of the processing chamber 2. Hence, the above-described gap does not exist, and generation of particles can be prevented. In addition, since microwaves can be supplied into the processing chamber 2 from the entire surface of the single dielectric ceiling plate 11, plasma can be diffused even if the above-described distance (gap) is small, and the device can be scaled down.

In the plasma processing apparatus 1 according to the present embodiment, the plurality of electromagnetic wave supply parts 5 are used to adjust the plasma density distribution. In the case of using the plurality of electromagnetic wave supply parts 5 placed on one dielectric ceiling plate 11, microwaves radiated from one antenna 65 spread through the dielectric ceiling plate 11. As a result, it becomes difficult to individually control the plurality of electromagnetic wave supply parts 5 to adjust the plasma distribution. As a result, the uniformity of plasma processing of the substrate W is affected.

Therefore, in the plasma processing apparatus 1 according to one embodiment, the plurality of recesses 66 in which the plurality of electromagnetic wave supply parts 5 are respectively installed are formed on the upper surface of the dielectric ceiling plate 11, that is, on the surface of the processing chamber 2 that faces the outer space.

### First Embodiment

### (Dielectric Ceiling Plate)

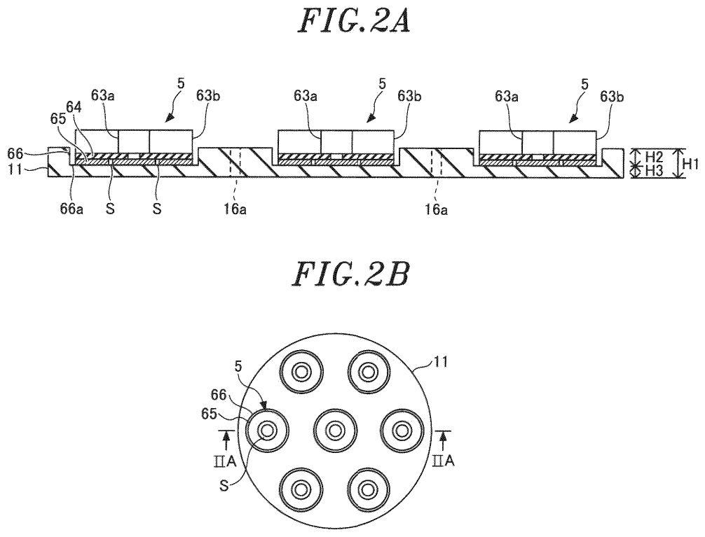

The dielectric ceiling plate 11 according to the first embodiment will be described with reference to FIGS. 2A and 2B. FIG. 2A is a cross-sectional view of the vicinity of the dielectric ceiling plate 11 according to the first embodiment, which is included in the plasma processing apparatus 1 shown in FIG. 1. FIG. 2B is a plan view of the dielectric ceiling plate 11 according to the first embodiment when viewed from the bottom surface side (the bottom portion 66a). FIG. 2A is a diagram taken along the IIA-IIA plane of FIG. 2B.

As shown in FIG. 2B, the dielectric ceiling plate 11 according to the first embodiment has seven recesses 66, i.e., one central recess and six outer peripheral recesses. Further, the regions (hereinafter, also referred to as “flat portions”) of the dielectric ceiling plate 11 other than the recesses 66 have the same height. The bottom surface of the dielectric ceiling plate 11 is flow without irregularities.

The plurality of electromagnetic wave supply parts 5 have the flat antennas 65 at the tip ends (end portions) thereof. Each of the antennas 65 has the ring-shaped slot S, and has the radiation surface that radiates microwaves from the slot S. The antennas 65 are installed only in the recesses 66. The antennas 65 are located at the bottom portions 66a of the plurality of recesses 66, and the radiation surfaces thereof are in contact with the bottom portions 66a. As shown in FIG. 2B, the planar shape of the recess 66 is similar to that of the antenna 65. In other words, the recess 66 and the antenna 65 have a perfect circular shape, and the diameter of the recess 66 is larger than that of the antenna 65.

As shown in FIG. 2A, the thickness of the dielectric ceiling plate 11 at the flat portions where the recesses 66 are not disposed is set to H1, the depth of the recesses 66 is set to H2, and the thickness of the dielectric ceiling plate 11 at the bottom portion 66a is set to H3. The thickness H1 is the vertical distance between the upper surface and the bottom surface of the dielectric ceiling plate 11. The depth H2 is the vertical distance between the upper surface of the dielectric ceiling plate 11 and the bottom portion 66a. The thickness H3 is the vertical distance between the bottom surface of dielectric ceiling plate 11 and the bottom portion 66a.

The thickness H3 of the dielectric ceiling plate 11 at the bottom portion 66a may be smaller than or equal to λ/8, where λ is the wavelength of microwaves propagating through the dielectric ceiling plate 11. When λ is the wavelength of electromagnetic waves (microwaves) in the dielectric ceiling plate 11, λ₀ is the free space wavelength of electromagnetic waves (microwaves) in vacuum, and εᵣ is a relative dielectric constant of the dielectric ceiling plate 11, λ=λ₀/√εᵣ is satisfied. In other words, due to the dielectric constant εᵣ of the dielectric ceiling plate 11, the wavelength λ of the microwaves in the dielectric ceiling plate 11 becomes shorter than the free space wavelength λ₀. Further, the lower limit of the thickness H3 of the dielectric ceiling plate 11 at the bottom portion 66a is 5 mm in consideration of intensity.

By making the thickness H3 of the dielectric ceiling plate 11 at the bottom portion 66a thinner than λ/8, it is possible to reduce the rate of transmission of microwaves in the horizontal direction (lateral direction), localize the electromagnetic field distribution, and efficiently control the plasma distribution.

In other words, the microwaves are radiated from the slots S to the bottom portion 66a mainly in the vertical direction, and the rate of transmission of the microwaves in the horizontal direction (lateral direction) is small. Therefore, the electromagnetic field of the microwaves radiated from the antennas 65 efficiently contributes to plasma generation near the bottom surface of the dielectric ceiling plate 11 below the recesses 66. Accordingly, the electromagnetic field distribution can be localized, and the plasma distribution can be efficiently controlled.

Further, the plurality of gas holes 16a penetrate through the flat portions of the dielectric ceiling plate 11 and supply a processing gas into the processing chamber 2. The microwaves that enter the flat portions spread uniformly in the flat portions. Moreover, the rate of transmission of the microwaves in the horizontal direction (lateral direction) is reduced due to the recesses 66. Therefore, the electric field intensity in the flat portions becomes low. By forming a gas channel at these flat portions, it is possible to prevent a gas from being decomposed to generate plasma in the gas channel before it enters the processing chamber 2.

### (Simulation 1)

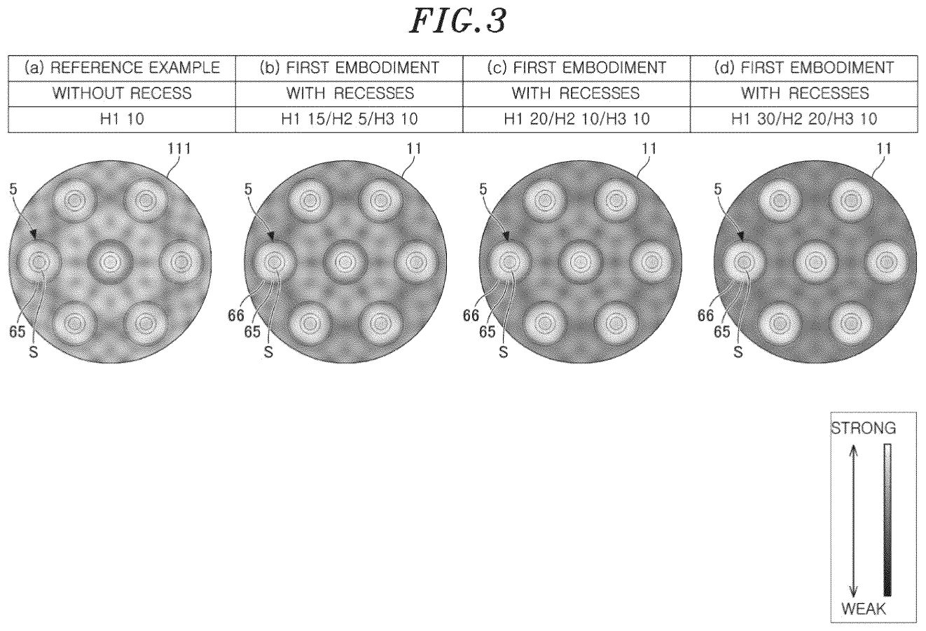

The configuration of the recess 66 of the dielectric ceiling plate 11 and the results of simulation 1 of the electric field intensity distribution according to the first embodiment will be described with reference to FIG. 3. FIG. 3, parts (a) to (d) show the dielectric ceiling plate 11 according to the first embodiment and result example 1 of the electric field intensity distribution.

FIG. 3, part (a) shows a reference example, and illustrates the electric field intensity distribution at the interface between a bottom surface of a dielectric ceiling plate 111 and plasma in the case of using the dielectric ceiling plate 111 with a flat upper surface having no recess 66. FIG. 3, parts (b) to (d) show the electric field intensity distribution at the interface between the bottom surface of the dielectric ceiling plate 11 and the plasma in the case of using the dielectric ceiling plate 11 according to the first embodiment.

In the conditions for simulation 1, seven electromagnetic wave supply parts 5 supply microwaves with a frequency of 860 MHz. In the reference example of FIG. 3, part (a), the thickness H1 of the dielectric ceiling plate 111 is set to 10 mm. In the first embodiment shown in FIG. 3, parts (b) to (d), the thickness H1 of the dielectric ceiling plate 11 is set to 15 mm, 20 mm, and 30 mm, and the depth H2 of the recess 66 is set to 5 mm, 10 mm, and 20 mm, respectively. Further, the thickness H3 of the dielectric ceiling plate 11 at the bottom portion 66a is set to 10 mm.

In the reference example of FIG. 3, part (a), the dielectric ceiling plate 111 is flat and has no recess. Therefore, the microwaves radiated from the slots S of the antennas 65 spread to the entire dielectric ceiling plate 111. In the case of the dielectric ceiling plate 111 of the reference example, even if the thickness H1 is changed to 20 mm or 30 mm, the microwaves spread to the entire dielectric ceiling plate 111.

On the other hand, in the first embodiment shown in FIG. 3, parts (b) to (d), the dielectric ceiling plate 11 has the recesses 66, and the thickness H3 of the dielectric ceiling plate 11 at the bottom portion 66a is set to be smaller than λ/8. Accordingly, the rate of transmission of the microwaves radiated to the bottom portion 66a in the horizontal direction (lateral direction) is reduced and, thus, the microwaves are transmitted mainly in the vertical direction, and the electric field intensity below the dielectric ceiling plate 11 having the recesses 66 in plan view can be increased. As a result, the results of simulation 1 shown in FIG. 3, parts (b) to (d) clearly show that the electric field intensity below the dielectric ceiling plate 11 where the recesses 66 are formed is higher than that below the dielectric ceiling plate 111 where the recesses 66 are not formed.

From the above results, it is clear that in the first embodiment shown in FIG. 3, parts (b) to (d), by making the thickness H3 of the dielectric ceiling plate 11 at the bottom portion 66a in the recess 66 of the dielectric ceiling plate 11 thinner than λ/8, the rate of transmission of microwaves in the horizontal direction (lateral direction) can be reduced. As a result, the electromagnetic field distribution can be localized under the dielectric ceiling plate 11 having the recesses 66, and the plasma distribution can be efficiently controlled.

### Second Embodiment

### (Dielectric Ceiling Plate)

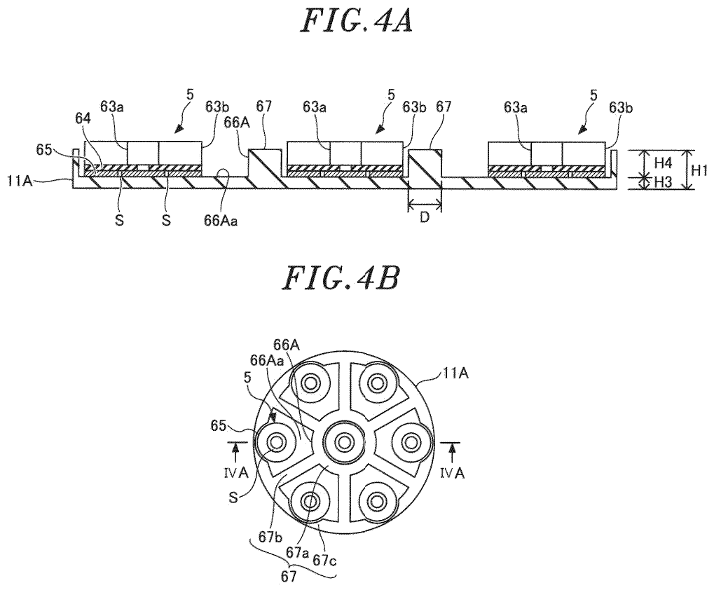

A dielectric ceiling plate 11A according to a second embodiment will be described with reference to FIGS. 4A and 4B. FIG. 4A is a cross-sectional view of the vicinity of the dielectric ceiling plate 11A according to the second embodiment, which is included in the plasma processing apparatus 1 shown in FIG. 1. FIG. 4B is a plan view of the dielectric ceiling plate 11A according to the second embodiment when viewed from the bottom surface side (bottom portion 66Aa). FIG. 4A is a diagram taken along the IVA-IVA of FIG. 4B.

The second embodiment is the same as the first embodiment except in that the shape of irregularities on the upper surface of the dielectric ceiling plate 11A is different from the shape of irregularities on the upper surface of the dielectric ceiling plate 11 according to the first embodiment. As shown in FIG. 4B, in the dielectric ceiling plate 11A according to the second embodiment, a protrusion illustrated as a bank 67 is disposed between adjacent electromagnetic wave supply parts 5 among one central electromagnetic wave supply part 5 and six outer peripheral electromagnetic wave supply parts 5. A bank 67a disposed between the outer peripheral electromagnetic wave supply parts 5 surrounding the central electromagnetic wave supply part 5 has an annular shape. A bank 67b between the outer peripheral electromagnetic wave supply parts 5 adjacent to each other has a rod shape, is connected to the bank 67a at the base end of the bank 67b, and extends radially outward from the bank 67a. The tip end of the bank 67b is connected to an approximately annular bank 67c surrounding the outer peripheral electromagnetic wave supply parts 5. The banks 67a, 67b, and 67c are collectively referred to as the bank 67.

By providing the bank 67 between adjacent electromagnetic wave supply parts 5, the concave portions other than the bank 67 that face the outer space of the processing chamber 2 serve as recesses 66A. Further, the bottom portions 66Aa of the recesses 66A of the dielectric ceiling plate 11A have the same height. The bottom surface of the dielectric ceiling plate 11A is flat without irregularities.

The plurality of electromagnetic wave supply parts 5 have the flat antennas 65 at the tip ends (end portions) thereof. Each of the antennas 65 has the ring-shaped slot S, and has the radiation surface that radiates microwaves from the slot S. The antennas 65 are installed only in the recesses 66A (i.e., in the regions surrounded by the banks 67). The antennas 65 are located at the bottom portions 66Aa of the plurality of recesses 66A, and the radiation surfaces thereof are in contact with the bottom portions 66Aa. As shown in FIG. 4B, the recess 66A formed at the center of the dielectric ceiling plate 11A has a shape similar to that of the electromagnetic wave supply part 5. Six peripheral recesses 66A formed at the outer peripheral portion have a substantially fan shape, and are recessed outward along the electromagnetic wave supply parts 5.

As shown in FIG. 4A, the thickness of the dielectric ceiling plate 11A at the portion where the bank 67 is located is set to H1, the height of the bank 67 is set to H4, and the thickness of the dielectric ceiling plate 11A at the bottom portion 66Aa is set to H3. The thickness H1 is the vertical distance between the upper surface of the bank 67 of the dielectric ceiling plate 11A and the bottom surface of the dielectric ceiling plate 11A. The height H4 of the bank 67 is the vertical distance between the upper surface of the bank 67 and the bottom portion 66Aa of the dielectric ceiling plate 11A. The thickness H3 is the vertical distance between the bottom surface of the dielectric ceiling plate 11A and the bottom portion 66Aa. As shown in FIG. 4A, the widths of the banks 67a and 67b is set to D. The widths D of the banks 67a and 67b are the same. The width of the bank 67c becomes partially smaller than the width D along the electromagnetic wave supply part 5. Further, the heights H4 of the banks 67a, 67b, and 67c are the same.

The height H4 and the width D of the bank 67 are within a range of λ/4±λ/8 (within a range of λ/8 to 3λ/8), where λ is the wavelength of microwaves propagating through the dielectric ceiling plate 11A. If each of the height H4 and width D of the bank 67 is set to 4 for the microwaves incident on the banks 67 from the recesses 66A, an effect similar to that of a choke is obtained, and an effect of suppressing the microwaves traveling in the horizontal direction (lateral direction) beyond the banks 67 is obtained. Even if each of the height H4 and the width D of the bank 67 is deviated from λ/4 by ±λ/8, the microwaves become weak. Therefore, if each of the height H4 and the width D of the bank 67 is within a range of λ/4±λ/8, it is considered that the bank 67 functions as a choke, and the microwaves do not propagate to neighboring recesses 66A beyond the bank 67.

Further, the upper limit and the lower limit of the thickness H3 of the dielectric ceiling plate 11A at the bottom portion 66Aa may be the same as the range of the thickness H3 of the dielectric ceiling plate 11 according to the first embodiment.

### (Simulation 2)

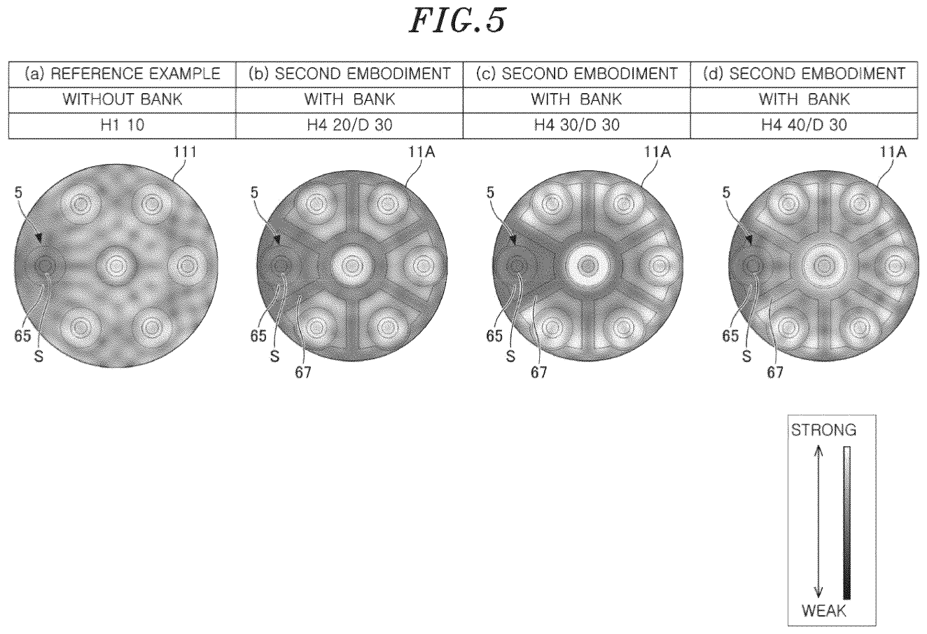

The configuration of the bank 67 of the dielectric ceiling plate 11A according to the second embodiment and the results of simulation 2 of the electric field intensity distribution will be described with reference to FIG. 5, parts (a) to (d). FIG. 5, parts (a) to (d) show the dielectric ceiling plate 11A according to the second embodiment and result example 2 of the electric field intensity distribution.

FIG. 5, part (a) shows a reference example, and illustrates the electric field intensity distribution at the interface between the bottom surface of the dielectric ceiling plate 111 and plasma in the case of using a dielectric ceiling plate 111 having a flat upper surface. FIG. 5, parts (b) to (d) show the electric field intensity distribution at the interface between the bottom surface of the dielectric ceiling plate 11A and the plasma in the case of using the dielectric ceiling plate 11A according to the second embodiment.

In the conditions for simulation 2, the width D of the bank is fixed, and the height H4 of the bank 67 is variable. Further, among the seven electromagnetic wave supply parts 5, only the electromagnetic wave supply part 5 located on the left side from the center is turned off, and the other six electromagnetic wave supply parts 5 supply microwaves having a frequency of 860 MHz. In the reference example of FIG. 5, part (a), the thickness H1 of the dielectric ceiling plate 111 is set to 10 mm. In the second embodiment shown in FIGS. 5B to 5D, the height H4 of the bank 67 is set to 20 mm, 30 mm, and 40 mm, and the width D of the bank 67 is set to 30 mm. Further, the thickness H3 of the dielectric ceiling plate 11A at the bottom portion 66Aa is set to 10 mm. The thickness H1 of the dielectric ceiling plate 11A is set to 30 mm, 40 mm, and 50 mm.

In the reference example of FIG. 5, part (a), the dielectric ceiling plate 111 is flat and has no recess. Therefore, the microwaves radiated from the slots S of the antennas 65 of the six electromagnetic wave supply parts 5 spread to the entire dielectric ceiling plate 111, and the flow of the microwaves to the antenna 65 of the electromagnetic wave supply part 5 located on the left side cannot be suppressed.

On the other hand, in FIG. 5, parts (b) to (d), the dielectric ceiling plate 11A has the banks 67, and each of the height H4 and the width D of the bank 67 is set to be within a range of λ/4±λ/8. Accordingly, the banks 67 have an effect similar to that of a choke, and an effect of suppressing microwaves traveling in the horizontal direction (lateral direction) beyond the banks 67 is obtained.

As a result, in the results of simulation 2 shown in FIG. 5, parts (b) to (d), the flow of the microwaves radiated from the slots S of the antennas 65 of the six electromagnetic wave supply parts 5 to the region of the electromagnetic wave supply part 5 located on the left side can be suppressed.

Further, in other conditions for simulation 2, the dielectric ceiling plate 11A was used, and the simulation was performed while setting the height H4 of the bank 67 to 5 mm and 10 mm and setting the width D of the banks 67 to 30 mm. Under such conditions, the function of the banks 67 that is similar to that of a choke was reduced, and the effect of suppressing microwaves traveling in the horizontal direction (lateral direction) beyond the banks 67 was reduced. This is considered to be because each of the height H4 and the width D of the bank 67 is not within the range of λ/4±λ/8 under these conditions.

### (Simulation 3)

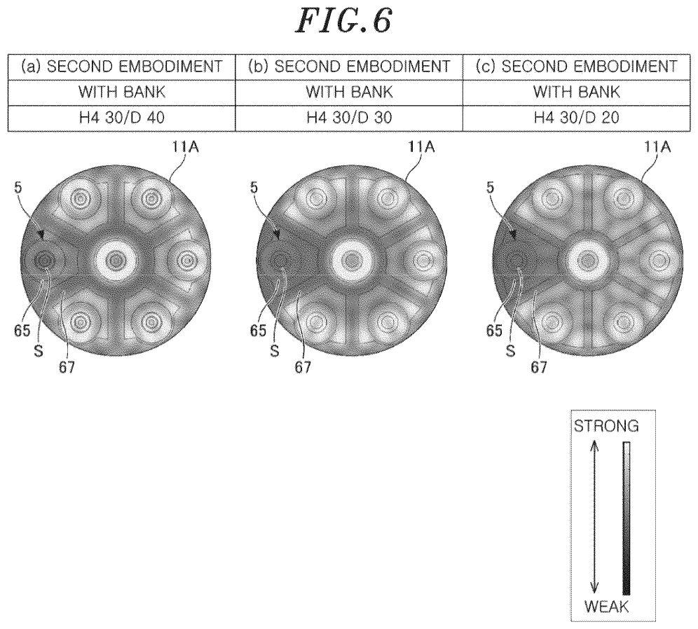

The configuration of the bank 67 of the dielectric ceiling plate 11A according to the second embodiment and the results of simulation 3 of the electric field intensity distribution will be described with reference to FIG. 6, parts (a) to (c). FIG. 6, parts (a) to (c) show the dielectric ceiling plate 11A according to the second embodiment and result example 3 of the electric field intensity distribution.

In the conditions for simulation 3, the height H4 of the bank is fixed, and the width D of the bank 67 is variable. Further, similarly to the simulation 2, among the seven electromagnetic wave supply parts 5, only the electromagnetic wave supply part 5 on the left side from the center is turned off, and the other six electromagnetic wave supply parts 5 supply microwaves with a frequency of 860 MHz. In the second embodiment shown in FIGS. 6A to 6C, the height H4 of the bank 67 is set to 30 mm, and the width D of the bank 67 is set to 40 mm, 30 mm, and 20 mm. Further, the thickness H3 of the dielectric ceiling plate 11A at the recess 66A is set to 10 mm. The thickness H1 of the dielectric ceiling plate 11A is set to 40 mm.

In FIG. 6, parts (a) to (c), each of the height H4 and the width D of the bank 67 is set to be within a range of λ/4±λ/8. Accordingly, the bank 67 has an effect similar to that of a choke, and the effect of suppressing microwaves traveling in the horizontal direction (lateral direction) beyond the banks 67 is obtained.

As a result, in the results of simulation 3 shown in FIG. 6, parts (a) to (c), the flow of the microwaves radiated from the slots S of the antennas 65 of the six electromagnetic wave supply parts 5 to the region of the electromagnetic wave supply part 5 located on the left side form the center can be suppressed.

In other conditions for simulation 3, the dielectric ceiling plate 11A was used, and the simulation was performed while setting the width D of the bank 67 to 10 mm, and setting the height H4 of the bank 67 to 30 mm. Under such conditions, the function of the bank 67 that is similar to that of a choke was reduced, and the effect of suppressing microwaves traveling in the horizontal direction (lateral direction) beyond the banks 67 was reduced. Similarly, the dielectric ceiling plate 11A was used and the simulation was performed while setting the width D of the bank 67 to 20 mm, 30 mm, and 40 mm, and setting the height H4 of the bank 67 to 40 mm. Also under such conditions, the function of the bank 67 that is similar to that of a choke was reduced, and the effect of suppressing microwaves traveling in the horizontal direction (lateral direction) beyond the banks 67 was reduced. This is considered to be because each of the height H4 and the width D of the bank 67 is not within the range of λ4±λ/8 under these conditions.

As described above, the dielectric ceiling plates 11 and 11A according to the first and second embodiments respectively have the recesses 66 and 66A on the upper surfaces thereof. Accordingly, the spread of the microwaves from one antenna 65 to the outside of the regions of the recesses 66 and 66A of the dielectric ceiling plate 11 can be suppressed, and the plasma distribution can be controlled for each region.

### Third Embodiment

### (Dielectric Ceiling Plate)

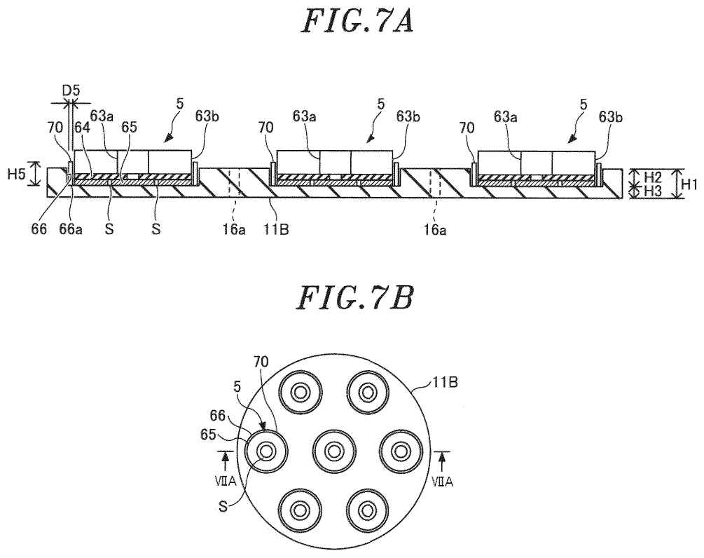

A dielectric ceiling plate 11B according to a third embodiment will be described with reference to FIGS. 7A and 7B. FIG. 7A is a cross-sectional view of the vicinity of the dielectric ceiling plate 11B according to the third embodiment, which is included the plasma processing apparatus 1 shown in FIG. 1. FIG. 7B is a plan view of the dielectric ceiling plate 11B according to the third embodiment when viewed from the bottom surface side (the bottom portion 66a). FIG. 7A is a diagram taken along the VIIA-VIIA plane of FIG. 7B.

As shown in FIG. 7B, the dielectric ceiling plate 11B according to the third embodiment has seven recesses 66, i.e., one central recess and six outer peripheral recesses, similarly to the dielectric ceiling plate 11 according to the first embodiment (see FIG. 2B). Further, the regions (hereinafter also referred to as “flat portions”) of the dielectric ceiling plate 11B other than the recesses 66 have the same height. The bottom surface of the dielectric ceiling plate 11B is flat without irregularities.

The plurality of electromagnetic wave supply parts 5 have the flat antennas 65 at the tip ends (end portions) thereof. Each of the antennas 65 has the ring-shaped slot S, and has the radiation surface that radiates microwaves from the slot S. The antennas 65 are installed only in the recesses 66. The antennas 65 are located at the bottom portions 66a of the plurality of recesses 66, and the radiation surfaces thereof are in contact with the bottom portions 66a. As shown in FIG. 7B, the planar shape of the recess 66 is similar to that of the antenna 65. In other words, the recess 66 and the antenna 65 have a perfect circular shape, and the diameter of the recess 66 is larger than that of the antenna 65.

As shown in FIG. 7A, the thickness of the dielectric ceiling plate 11B at the flat portions where the recesses 66 are not disposed is set to H1, the depth of the recesses 66 is set to H2, and the thickness of the dielectric ceiling plate 11B at the bottom portion 66a is set to H3. The thickness H1 is the vertical distance between the upper surface and the bottom surface of the dielectric ceiling plate 11B. The depth H2 is the vertical distance between the upper surface of the dielectric ceiling plate 11B and the bottom portion 66a. The thickness H3 is the vertical distance between the bottom surface of dielectric ceiling plate 11b and the bottom portion 66a.

The thickness H3 of the dielectric ceiling plate 11 at the bottom portion 66a may be smaller than or equal to λ/8, where λ is the wavelength of microwaves propagating through the dielectric ceiling plate 11B. When A is the wavelength of electromagnetic waves (microwaves) in the dielectric ceiling plate 11B, λ₀ is the free space wavelength of electromagnetic waves (microwaves) in vacuum, and εᵣ is a relative dielectric constant of the dielectric ceiling plate 11B, λ=λ₀/√εᵣ is satisfied. In other words, due to the dielectric constant εᵣ of the dielectric ceiling plate 11B, the wavelength λ of the microwaves in the dielectric ceiling plate 11 becomes shorter than the free space wavelength λ₀. Further, the lower limit of the thickness H3 of the dielectric ceiling plate 11B at the bottom portion 66a is 5 mm in consideration of intensity.

By making the thickness H3 of the dielectric ceiling plate 11B at the bottom portion 66a thinner than λ/8, it is possible to reduce the rate of transmission of microwaves in the horizontal direction (lateral direction), localize the electromagnetic field distribution, and efficiently control the plasma distribution.

In other words, the microwaves are radiated from the slots S to the bottom portion 66a mainly in the vertical direction, and the rate of transmission of the microwaves in the horizontal direction (lateral direction) is small. Therefore, the electromagnetic field of the microwaves radiated from the antennas 65 efficiently contributes to plasma generation near the bottom surface of the dielectric ceiling plate 11B below the recesses 66. Accordingly, the electromagnetic field distribution can be localized, and the plasma distribution can be efficiently controlled.

Further, the plurality of gas holes 16a penetrate through the flat portions of the dielectric ceiling plate 11B and supply a processing gas into the processing chamber 2. The microwaves that enter the flat portions spread uniformly in the flat portions. Moreover, the rate of transmission of the microwaves in the horizontal direction (lateral direction) is reduced due to the recesses 66. Therefore, the electric field intensity in the flat portions becomes low. By forming a gas channel at these flat portions, it is possible to prevent a gas from being decomposed to generate plasma in the gas channel before it enters the processing chamber 2.

Further, a choke 70, which is an annular protrusion located at the outer peripheral portion of the antenna 65, is disposed in the recess 66 of the dielectric ceiling plate 11B. The choke 70 has an annular shape (circular shape) when viewed from above, and is disposed to surround the outside of the antenna 65 when viewed from above. The choke 70 has a rectangular cross section, and has cylindrical inner and outer circumferential surfaces, an annular flat bottom surface that connects the lower end of the inner circumferential surface and the lower end of the outer circumferential surface, and an annular flat upper surface that connects the upper end of the inner circumferential surface and the upper end of the outer circumferential surface. The choke 70 includes an annular dielectric made of the same material (alumina (Al₂O₃)) as that of the dielectric ceiling plate 11B, and a conductor (metal) that is disposed on the surface of the dielectric and allows microwaves to propagate therethrough. Further, the conductor (metal) is provided to cover three surfaces, i.e., the inner circumferential surface, the outer circumferential surface, and the upper surface, of the choke 70. Further, the planar shape of the inner circumferential surface of the choke 70 is similar to that of the antenna 65, and the planar shape of the outer circumferential surface of the choke 70 is similar to that of the recess 66. Further, the choke 70 is disposed in the recess 66. In other words, the inner diameter of the choke 70 is larger than the diameter of the antenna 65, and the outer diameter of the choke 70 is smaller than the diameter of the recess 66.

Here, the height of the choke 70 is set to H5. Further, the width of the choke 70 is set to D5. The height H5 of the choke 70 is preferably λ/4. Accordingly, the microwaves propagating on the bottom surface of the choke 70 and the microwaves propagating on the inner, upper, and outer circumferential surfaces of the choke 70 weaken each other, thereby suppressing microwaves traveling in the horizontal direction (lateral direction) beyond the chokes 70. Further, the height H5 of the choke 70 is not limited thereto, the microwaves traveling in the horizontal direction (lateral direction) beyond the chokes 70 can be suppressed even when the height of the choke 70 is within a range of λ/4'λ/8 (within a range of λ/8 to 3λ/8: λ/8≤H5≤3λ/8).

Further, it is preferable that the width D5 of the choke 70 is approximately the same as the thickness H3 of the dielectric ceiling plate 11B in the recess 66. Accordingly, the microwaves propagating on the bottom surface of the choke 70 and the microwaves propagating on the inner circumferential surface, the upper surface, and the outer circumferential surface of the choke 70 are branched into two, and preferably can cancel each other out. Specifically, the width D5 of the choke 70 may be preferably within a range of 0.5 to 2 times (0.5×H3≤D5≤2×H3) the thickness H3 of the dielectric ceiling plate 11B in the recess 66.

Although the dielectric ceiling plate 11B having the ring-shaped dielectric (the choke 70) as a separate member has been described, the present disclosure is not limited thereto. A ring-shaped protrusion (corresponding to the choke 70) standing up from the recess 66 of the dielectric ceiling plate 11B may be integrally formed.

### (Simulation 4)

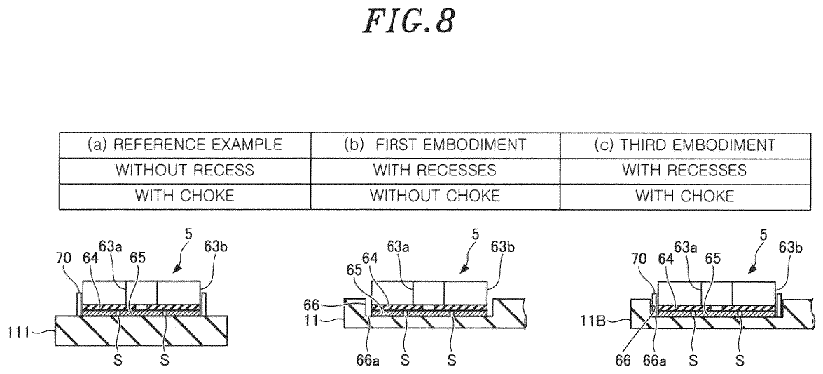

The results of simulation 4 of the electric field intensity distribution of the dielectric ceiling plate 11B according to the third embodiment will be described with reference to FIGS. 8 to 10. FIG. 8, parts (a) to (c) are cross-sectional views of the dielectric ceiling plate 111 according to the reference example, the dielectric ceiling plate 11 according to the first embodiment, and the dielectric ceiling plate 11B according to the third embodiment, respectively.

The dielectric ceiling plate 111 according to the reference example shown in FIG. 8, part (a) has a flat upper surface without the recesses 66. Further, the dielectric ceiling plate 111 according to the reference example has the chokes 70 on the upper surface thereof. The thickness H1 of the dielectric ceiling plate 111 is 25 mm. Further, the height H5 of the choke 70 is λ/4 (λ₀=340 mm, εᵣ≈10, and λ/4=27 mm in the case of Al₂O₃).

The dielectric ceiling plate 11 according to the first embodiment shown in FIG. 8, part (b) has the recesses 66. Further, the dielectric ceiling plate 11 according to the first embodiment does not have the choke 70. The thickness H1 of the dielectric ceiling plate 11 is 25 mm. The thickness H3 of the dielectric ceiling plate 11 in the recess 66 is 10 mm (λ/8 or less).

The dielectric ceiling plate 11B according to the third embodiment shown in FIG. 8, part (c) has the recess 66. Further, in the dielectric ceiling plate 11B according to the third embodiment, the choke 70 is disposed in the recess 66. The thickness H1 of the dielectric ceiling plate 11B is 25 mm. The thickness H3 of the dielectric ceiling plate 11B in the recess 66 is 10 mm (λ/8 or less). Further, the height H5 of the choke 70 is λ/4.

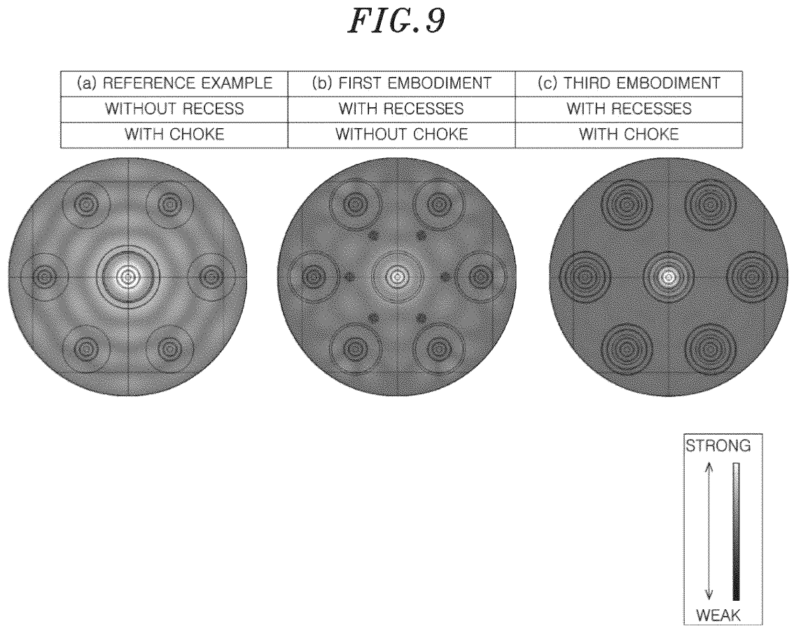

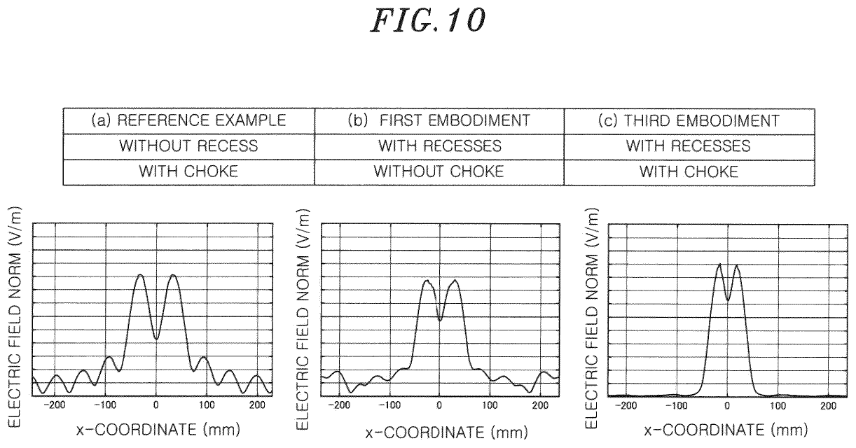

FIG. 9, parts (a) to (c) show result examples of the electric field intensity distribution in the dielectric ceiling plate 111 according to the reference example, the dielectric ceiling plate 11 according to the first embodiment, and the dielectric ceiling plate 11B according to the third embodiment, respectively. FIG. 10, parts (a) to (c) are graphs showing results examples of the electric field intensity in the radial direction in the dielectric ceiling plate 111 according to the reference example, the dielectric ceiling plate 11 according to the first embodiment, and the dielectric ceiling plate 11B according to the third embodiment, respectively. In FIG. 10, parts (a) to (c), the vertical axis represents the electric field intensity, and the horizontal axis represents the position in the radial direction with the center position of the antenna 65 being 0 (zero).

In the conditions for simulation 4, microwaves with a frequency of 860 MHz are supplied from the central electromagnetic wave supply part 5.

In the dielectric ceiling plate 111 according to the reference example shown in FIG. 9, part (a) and FIG. 10, part (a), even if the choke 70 is provided at the flat dielectric ceiling plate 111 having no recess, the microwave shielding effect was not obtained. Specifically, the electric field intensity at the position where the radius R is 175 [mm] was about ⅕ of the electric field intensity directly below the antenna 65.

In the dielectric ceiling plate 11 according to the first embodiment shown in FIG. 9, part (b) and FIG. 10, part (b), the microwave shielding effect was obtained by providing the antenna 65 in the recess 66. Specifically, the electric field intensity at the position where the radius R is 175 [mm] was about 1/9 of the electric field intensity directly below the antenna 65.

In the dielectric ceiling plate 11B according to the third embodiment shown in FIG. 9, part (c) and FIG. 10, part (c), the enhanced microwave shielding effect was obtained by providing the antenna 65 and the choke 70 in the recess 66. Specifically, the electric field intensity at the position where the radius R is 175 [mm] was about 1/100 of the electric field intensity directly below the antenna 65.

From the above results, in the third embodiment shown in FIG. 9, part (c) and FIG. 10, part (c), it is clear that the rate of transmission of microwaves in the horizontal direction (lateral direction) can be reduced by making the thickness H3 of the dielectric ceiling plate 11B at the bottom portion 66a of the recess 66 of the dielectric ceiling plate 11B thinner than λ/8 and providing the choke 70 in the recess 66. As a result, the electromagnetic field distribution can be localized under the dielectric ceiling plate 11B having the recesses) 66, and the plasma distribution can be efficiently controlled.

The electric field intensity of microwaves propagating to the choke 70 disposed at the bottom portion 66a of the dielectric ceiling plate 11B according to the third embodiment becomes higher than the electric field intensity of microwaves propagating to the choke 70 disposed on the upper surface of the dielectric ceiling plate 111 according to the reference example. Therefore, by providing the choke 70 at the bottom portion 66a where the electric field intensity is high, the microwaves transmitted in the horizontal direction can be preferably attenuated.

As described above, in accordance with the plasma processing apparatus 1 having the dielectric ceiling plates 11, 11A, and 11B according to the first to third embodiments, it is possible to localize the electric field intensity distribution in the dielectric ceiling plate due to the microwaves supplied from the plurality of electromagnetic wave supply parts 5, and easily control the plasma distribution.

In particular, by making the thickness H3 of the dielectric ceiling plate 11 according to the first embodiment at the bottom portion 66a in the recess 66 thinner than λ/8, it is possible to reduce the rate of transmission of microwaves in the horizontal direction (lateral direction), localize the electromagnetic field distribution, and efficiently control the plasma distribution.

Further, by setting each of the height H4 and the width D of the bank 67 of the dielectric ceiling plate 11A according to the second embodiment to be within a range of λ/4±λ/8, an effect similar to that of a choke can be obtained, and the flow of microwaves radiated from the antenna 65 of one electromagnetic wave supply part 5 to the regions of the adjacent electromagnetic wave supply parts 5 can be efficiently suppressed.

Further, in the dielectric ceiling plate 11B according to the third embodiment, by providing the choke 70 in the recess 66, the flow of microwaves radiated from the antenna 65 of one electromagnetic wave supply part 5 to the regions of the adjacent electromagnetic wave supply parts 5 can be efficiently suppressed.

Although the case where the dielectric ceiling plates 11, 11A, and 11B and the dielectric of the choke 70 are made of alumina has been described, the present disclosure is not limited thereto, and they may be made of quartz (SiO₂), silicon nitride (SiN), or the like.

The plasma processing apparatus according to the embodiments disclosed herein should be considered as examples and not restrictive in all respects. The embodiments can be modified and improved in various ways without departing from the scope and spirit of the appended claims. The elements described in the foregoing multiple embodiments can assume other configurations within a consistent range and can be combined within a consistent range.

The embodiments disclosed above include, for example, the following aspects.

### (Appendix 1)

A plasma processing apparatus comprising:
a processing chamber having an upper opening;
a dielectric ceiling plate that partitions an inner space and an outer space of the processing chamber to close the opening, and has a plurality of recesses formed on a surface facing the outer space; and
a plurality of electromagnetic wave supply parts respectively having flat antennas, respectively installed in the plurality of recesses, and configured to supply electromagnetic waves into the processing chamber,
wherein the antennas are disposed at bottom portions of the plurality of recesses.

### (Appendix 2)

The plasma processing apparatus of appendix 1, wherein a thickness of the dielectric ceiling plate in the plurality of recesses is λ/8 or less, where λ is a wavelength of electromagnetic waves propagating through the dielectric ceiling plate.

### (Appendix 3)

The plasma processing apparatus of appendix 1 or 2, wherein the dielectric ceiling plate has a plurality of gas holes that penetrate in a thickness direction through regions other than the plurality of recesses and are configured to supply a processing gas into the processing chamber.

### (Appendix 4)

The plasma processing apparatus of any one of appendices 1 to 3, wherein the plurality of recesses have a circular planar shape or a planar shape that is similar to a planar shape of the antenna.

### (Appendix 5)

The plasma processing apparatus of any one of appendices 1 to 3, wherein in the dielectric ceiling plate, a bank is provided between the adjacent electromagnetic wave supply parts, so that the plurality of recesses are surrounded by the bank.

### (Appendix 6)

The plasma processing apparatus of appendix 5, wherein a height of the bank and a width of the bank are within a range of λ/4±λ/8.

### (Appendix 7)

The plasma processing apparatus of appendix 2, wherein a protrusion located at an outer peripheral portion of the antenna is disposed in the recess, and the height of the protrusion is within a range of λ/4±λ/8.

### (Appendix 8)

The plasma processing apparatus of appendix 7, wherein the protrusion surrounds the antenna in plan view.

### (Appendix 9)

The plasma processing apparatus of appendix 7 or 8, wherein the width of the protrusion is within a range of 0.5 to 2 times a thickness of the dielectric ceiling plate in the recess.

### (Appendix 10)

The plasma processing apparatus of any one of appendices 7 to 9, wherein the plurality of recesses have a circular planar shape, and
the protrusion is provided for each of the plurality of recesses.

### (Appendix 11)

The plasma processing apparatus of any one of appendices 1 to 6, wherein the antenna is disposed at an end portion of each of the plurality of electromagnetic wave supply parts, has a ring-shaped slot, and has a radiation surface that radiates electromagnetic waves from the slot.

### (Appendix 12)

The plasma processing apparatus of appendix 11, wherein the antenna radiates electromagnetic waves from the radiation surface, so that an electric field intensity of plasma below the dielectric ceiling plate where the recesses are formed in plan view becomes higher than an electric field intensity of plasma below the dielectric ceiling plate where the recesses are not formed.

1. A plasma processing apparatus comprising:
a processing chamber having an upper opening;
a dielectric ceiling plate that partitions an inner space and an outer space of the processing chamber to close the opening, and has a plurality of recesses formed on a surface facing the outer space; and
a plurality of electromagnetic wave supply parts respectively having flat antennas, respectively installed in the plurality of recesses, and configured to supply electromagnetic waves into the processing chamber,
wherein the antennas are disposed at bottom portions of the plurality of recesses.

2. The plasma processing apparatus of claim 1, wherein a thickness of the dielectric ceiling plate in the plurality of recesses is λ/8 or less, where λ is a wavelength of electromagnetic waves propagating through the dielectric ceiling plate.

3. The plasma processing apparatus of claim 1, wherein the dielectric ceiling plate has a plurality of gas holes that penetrate in a thickness direction through regions other than the plurality of recesses and are configured to supply a processing gas into the processing chamber.

4. The plasma processing apparatus of claim 1, wherein the plurality of recesses have a circular planar shape or a planar shape that is similar to a planar shape of the antenna.

5. The plasma processing apparatus of claim 1, wherein in the dielectric ceiling plate, a bank is provided between the adjacent electromagnetic wave supply parts, so that the plurality of recesses are surrounded by the bank.

6. The plasma processing apparatus of claim 2, wherein in the dielectric ceiling plate, a bank is provided between the adjacent electromagnetic wave supply parts, so that the plurality of recesses are surrounded by the bank.

7. The plasma processing apparatus of claim 3, wherein in the dielectric ceiling plate, a bank is provided between the adjacent electromagnetic wave supply parts, so that the plurality of recesses are surrounded by the bank.

8. The plasma processing apparatus of claim 5, wherein a height of the bank and a width of the bank are within a range of λ/4±λ/8.

9. The plasma processing apparatus of claim 6, wherein a height of the bank and a width of the bank are within a range of λ/4±λ/8.

10. The plasma processing apparatus of claim 7, wherein a height of the bank and a width of the bank are within a range of λ/4±λ/8.

11. The plasma processing apparatus of claim 2, wherein a protrusion located at an outer peripheral portion of the antenna is disposed in the recess, and
the height of the protrusion is within a range of λ4±λ/8.

12. The plasma processing apparatus of claim 11, wherein the protrusion surrounds the antenna in plan view.

13. The plasma processing apparatus of claim 11, wherein the width of the protrusion is within a range of 0.5 to 2 times a thickness of the dielectric ceiling plate in the recess.

14. The plasma processing apparatus of claim 11, wherein the plurality of recesses have a circular planar shape, and
the protrusion is provided for each of the plurality of recesses.

15. The plasma processing apparatus of claim 1, wherein the antenna is disposed at an end portion of each of the plurality of electromagnetic wave supply parts, has a ring-shaped slot, and has a radiation surface that radiates electromagnetic waves from the slot.

16. The plasma processing apparatus of claim 2, wherein the antenna is disposed at an end portion of each of the plurality of electromagnetic wave supply parts, has a ring-shaped slot, and has a radiation surface that radiates electromagnetic waves from the slot.

17. The plasma processing apparatus of claim 3, wherein the antenna is disposed at an end portion of each of the plurality of electromagnetic wave supply parts, has a ring-shaped slot, and has a radiation surface that radiates electromagnetic waves from the slot.

18. The plasma processing apparatus of claim 15, wherein the antenna radiates electromagnetic waves from the radiation surface, so that an electric field intensity of plasma below the dielectric ceiling plate where the recesses are formed in plan view becomes higher than an electric field intensity of plasma below the dielectric ceiling plate where the recesses are not formed.

19. The plasma processing apparatus of claim 16, wherein the antenna radiates electromagnetic waves from the radiation surface, so that an electric field intensity of plasma below the dielectric ceiling plate where the recesses are formed in plan view becomes higher than an electric field intensity of plasma below the dielectric ceiling plate where the recesses are not formed.

20. The plasma processing apparatus of claim 17, wherein the antenna radiates electromagnetic waves from the radiation surface, so that an electric field intensity of plasma below the dielectric ceiling plate where the recesses are formed in plan view becomes higher than an electric field intensity of plasma below the dielectric ceiling plate where the recesses are not formed.
